(19) United States
(12) Patent Application Publication
(10) Pub. No.: US 2026/0123314 A1
(43) Pub. Date: Apr. 30, 2026

(54) PROTECTIVE FILM FORMING AGENT FOR SILICON-BASED SUBSTRATE, METHOD FOR PROCESSING SILICON-BASED SUBSTRATE, AND METHOD FOR MANUFACTURING SEMICONDUCTOR DEVICE

(71) Applicant: TOKYO OHKA KOGYO CO., LTD., Kanagawa (JP)

(72) Inventor: Kohei SERIZAWA, Kanagawa (JP)

(21) Appl. No.: 19/362,559

(22) Filed: Oct. 20, 2025

(30) Foreign Application Priority Data
Oct. 29, 2024 (JP) 2024-189868

(51) Int. Cl. H01L 21/308; H01L 21/02

(52) U.S. Cl. CPC H10P 50/695; H10P 14/6309; H10P 50/692

(57) ABSTRACT

Provided are a protective film forming agent for a silicon-based substrate, the protective film forming agent containing a silylating agent and a solvent having a Hildebrand SP value of 17.5 or less, a method for processing a silicon-based substrate using the same, and a method for manufacturing a semiconductor device using the same.

### CROSS-REFERENCE TO RELATED APPLICATIONS

The present application claims priority based on Patent Application No. 2024-189868 filed with the Japan Patent Office on Oct. 29, 2024, the entire contents of which are incorporated herein by reference.

### BACKGROUND OF THE INVENTION

### 1. Technical Field

The present invention relates to a protective film forming agent for a silicon-based substrate, a method for processing a silicon-based substrate, and a method for manufacturing a semiconductor device.

### 2. Description of the Related Art

In a step of manufacturing a semiconductor device, for example, there is performed a process of etching a multilayer substrate with a silicon oxide film (SiO₂) or a silicon nitride film (SiN) formed on a substrate, such as a silicon-based substrate. At that time, formation of an etching protective film using a silylating agent is used for controlling an etching amount and selective etching. In addition, if the etching protective film can be formed on an exposed portion of the silicon-based substrate in the presence of resist, the degree of freedom in pattern formation of the semiconductor device can be improved.

As a method related to such a technique, Patent Document 1 (JP 2016-105519 A) discloses a method for processing a substrate including a moisture removing step of removing moisture adsorbed into a silicon oxide film from a substrate having a surface on which a silicon nitride film and the silicon oxide film are exposed, a silylating step of supplying a silylating agent to the substrate after the moisture removing step, and an etching step of supplying an etching agent to the substrate after the silylating step.

### PATENT LITERATURE

Patent Document 1: JP 2016-105519 A

### SUMMARY OF THE INVENTION

The above-described forming agent using the silylating agent is usually supplied to the substrate by a vapor method (method in which the silylating agent is converted into vapor and brought into contact with the substrate). Patent Document 1 (JP 2016-105519 A) also discloses a method and the like for forming an etching protective film by introducing the vapor of the silylating agent into a chamber and the like. As a result of intensive studies by the inventor on this point, it has been found that the supply of the silylating agent by the conventional vapor method has a problem that reactivity to the silicon-based substrate is low and etching protective capability in that case is low. Furthermore, as a result of detailed research by the inventor, it has been found that in the above-described conventional technique using the silylating agent as a protective film forming agent for a silicon-based substrate, a forming agent excellent in not damaging the resist and being capable of forming a protective film cannot be achieved and there is room for improvement.

The present invention has been made in view of such circumstances, and an object thereof is to provide a protective film forming agent for a silicon-based substrate, a method for processing a silicon-based substrate, and a method for manufacturing a semiconductor device that are capable of forming a protective film on a silicon-based substrate without damaging resist.

As a result of intensive studies to achieve the above-described object, the present inventor has found that a protective film forming agent for a silicon-based substrate contains a silylating agent and a solvent having a Hildebrand SP value of 17.5 or less, and has completed the present invention.

In other words, the present invention is as follows.

<1>

A protective film forming agent for a silicon-based substrate, the protective film forming agent containing a silylating agent and a solvent having a Hildebrand SP value of 17.5 or less.

<2>

The protective film forming agent for a silicon-based substrate according to <1>, in which the silylating agent is at least one kind selected from the group consisting of hexamethyldisilazane, trimethylsilyldimethylamine, and bisdimethylaminodimethylsilane.

<3>

The protective film forming agent for a silicon-based substrate according to <1> or <2>, in which the solvent is at least one kind selected from the group consisting of a hydrocarbon-based solvent, an ester-based solvent having one ester bond in a molecule, and an ether-based solvent having one ether bond in a molecule.

<4>

The protective film forming agent for a silicon-based substrate according to any one of <1> to <3>, in which the content of the silylating agent is 1% by mass or more and 20% by mass or less.

<5>

The protective film forming agent for a silicon-based substrate according to any one of <1> to <4>, in which a total of the content of a hydrocarbon-based solvent, an ester-based solvent having one ester bond in a molecule, and an ether-based solvent having one ether bond in a molecule is 80% by mass or more and 100% by mass or less in a total amount of the solvent.

<6>

The protective film forming agent for a silicon-based substrate according to any one of <1> to <5>, in which a total of the content of the silylating agent and the content of the solvent in the protective film forming agent for a silicon-based substrate is 80% by mass or more and 100% by mass or less.

<7>

The protective film forming agent for a silicon-based substrate according to any one of <1> to <6>, in which a protective film can be formed on a silicon-based substrate including an organic film at least part of which is exposed.

<8>

A method for processing a silicon-based substrate, the method including: (1) a step of subjecting, to oxidation processing, a surface of a silicon-based substrate including an organic film at least part of which is exposed; and (2) a step of forming a protective film by bringing a protective film forming agent for a silicon-based substrate into contact with at least part of the surface of the silicon-based substrate subjected to the oxidation processing, in which the protective film forming agent for a silicon-based substrate contains a silylating agent and a solvent having a Hildebrand SP value of 17.5 or less.

<9>

The method for processing a silicon-based substrate according to <8>, in which the step (2) is a step of forming the protective film by immersing at least part of the surface of the silicon-based substrate subjected to the oxidation processing in the protective film forming agent for a silicon-based substrate.

<10>

The method for processing a silicon-based substrate according to <8> or <9>, in which the silicon-based substrate includes one or more kinds of materials selected from the group consisting of silicon oxide, carbon-containing silicon oxide, silicon nitride, silicon carbide, silicon carbonitride, silicon oxynitride, silicon oxycarbonitride, and silicon.

<11>

A method for manufacturing a semiconductor device, the method including: (1) a step of subjecting, to oxidation processing, a surface of a silicon-based substrate including an organic film at least part of which is exposed; and (2) a step of forming a protective film by bringing a protective film forming agent for a silicon-based substrate into contact with at least part of the surface of the silicon-based substrate subjected to the oxidation processing, in which the protective film forming agent for a silicon-based substrate contains a silylating agent and a solvent having a Hildebrand SP value of 17.5 or less.

<12>

The method for manufacturing a semiconductor device according to <11>, in which the step (2) is a step of forming the protective film by immersing at least part of the surface of the silicon-based substrate subjected to the oxidation processing in the protective film forming agent for a silicon-based substrate.

<13>

The method for manufacturing a semiconductor device according to <11> or <12>, further including, after the step (2), a step of etching the silicon-based substrate on which the protective film is formed.

<14>

The method for manufacturing a semiconductor device according to any one of <11> to <13>, in which the silicon-based substrate includes one or more kinds of materials selected from the group consisting of silicon oxide, carbon-containing silicon oxide, silicon nitride, silicon carbide, silicon carbonitride, silicon oxynitride, silicon oxycarbonitride, and silicon.

The present invention makes it possible to provide a protective film forming agent for a silicon-based substrate, a method for processing a silicon-based substrate, and a method for manufacturing a semiconductor device that are capable of forming a protective film on a silicon-based substrate without damaging resist.

### DETAILED DESCRIPTION

Hereinafter, an embodiment for carrying out the present invention (hereinafter, simply referred to as “the present embodiment”) will be described in detail. The present embodiment below is an example for describing the present invention, and it is not intended to limit the present invention to the following description. The present invention can be appropriately modified and implemented within the scope of the gist thereof. Furthermore, unless otherwise specified, the configurations and parameters disclosed herein may be arbitrarily combined. In addition, unless otherwise specified, the upper and lower limits of the values disclosed herein may be arbitrarily combined. Moreover, as used herein, the transitional term “comprise” and its variants (e.g., “comprising,” “comprises”) may be replaced with “consist essentially of” or “consist of” and their respective variants, as appropriate.

### <Protective Film Forming Agent for Silicon-Based Substrate>

A protective film forming agent for a silicon-based substrate according to the present embodiment is a protective film forming agent for a silicon-based substrate, the protective film forming agent containing a silylating agent and a solvent having a Hildebrand SP value (hereinafter, may be simply abbreviated as “SP value”) of 17.5 or less. The solvent having a Hildebrand SP value of 17.5 or less is used as a solvent used in combination with the silylating agent, whereby a protective film can be formed on a silicon-based substrate without damaging resist. In other words, the protective film forming agent for a silicon-based substrate according to the present embodiment can form a protective film without dissolving resist. As described above, the protective film forming agent for a silicon-based substrate according to the present embodiment is excellent in a property of inhibiting resist dissolution (resist dissolution inhibiting property) and etching protective capability. The protective film forming agent for a silicon-based substrate according to the present embodiment is used in a wet method, whereby the resist dissolution inhibiting property and the etching protective capability can be further improved. Therefore, it is preferable to use the protective film forming agent for a silicon-based substrate by the wet method.

Although the reason why the protective film forming agent for a silicon-based substrate according to the present embodiment can form the protective film without dissolving the resist is not certain, the reason is presumed to be as follows. First, since the solvent having an SP value of 17.5 or less is used, it is possible to inhibit the resist from being unintentionally dissolved during processing. In addition, since the SP value is 17.5 or less, it is possible to inhibit interaction between the solvent and the silylating agent and to promote reaction between the silylating agent and the silicon-based substrate. From the above, it is presumed that the above-described effects can be obtained (However, the mechanism and effect according to the present embodiment are not limited to these.).

### (Silicon-Based Substrate)

The silicon-based substrate for which the protective film forming agent for a silicon-based substrate according to the present embodiment is used is not particularly limited. However, the silicon-based substrate preferably includes one or more kinds of materials selected from the group consisting of, for example, silicon oxide, carbon-containing silicon oxide, silicon nitride, silicon carbide, silicon carbonitride, silicon oxynitride, silicon oxycarbonitride, and silicon. In the case of a silicon-based substrate including such a material, a protective film can be formed more effectively using the protective film forming agent for a silicon-based substrate according to the present embodiment, without dissolving resist. In addition, a protective film can be formed on an exposed portion of a silicon-based substrate having a surface on which patterned resist according to the present embodiment is present and at least part of the patterned resist is exposed. In particular, the protective film can be formed more effectively using the wet method without dissolving the resist.

### (Silylating Agent)

The silylating agent is not particularly limited, but is preferably, for example, a compound containing a silazane skeleton or a compound containing a siloxane skeleton. In addition, a specific example of the silylating agent is more preferably at least one kind selected from the group consisting of hexamethyldisilazane (HMDS), trimethylsilyldimethylamine (TMSDMA), and bisdimethylaminodimethylsilane (BDMADMS). By using such a compound, it is possible to further improve the property of inhibiting resist dissolution and the etching protective capability.

The content of the silylating agent in the protective film forming agent for a silicon-based substrate according to the present embodiment is not particularly limited, but is preferably 1% by mass or more and 20% by mass or less. The lower limit of the content is more preferably 3% by mass or more, and even more preferably 5% by mass or more. The upper limit of the content is more preferably 17% by mass or less, and even more preferably 15% by mass or less. The content of the silylating agent is in such a range, whereby it is possible to further improve the property of inhibiting resist dissolution and the etching protective capability.

### (Solvent)

The solvent has an SP value of 17.5 or less. The SP value is a Hildebrand SP value, is a dissolution parameter defined by the square root of cohesive energy density, and is an indicator of the dissolution behavior of the solvent. The Hildebrand SP value can be obtained by the following Formula (1):

$$SP value = {( {δ}_{d}^{2} + {δ}_{p}^{2} + {δ}_{h}^{2} )}^{1 / 2} \qquad ( 1 )$$

where δ_{d} represents a dispersion force term, δₚ represents a polarity term, and δₕ represents a hydrogen bond term.

As examples, the SP values of some solvents are shown in Table 1 (Note that the solvent used in the present embodiment is not limited to the following.).

TABLE 1

| Solvent | SP value | Solvent | SP value |
|---|---|---|---|
| Hexane | 14.9 | Ethylene glycol | 18.6 |
| | | monoisobutyl ether | |
| Tridecane | 15.6 | Propylene glycol monomethyl | 19.3 |
| | | ether acetate (PGMEA) | |
| Tetradecane | 15.6 | Acetone | 20.0 |
| Decane | 15.7 | Propylene glycol monomethyl | 20.4 |
| | | ether (PGME) | |
| Dibutyl ether | 15.9 | Isopropyl alcohol | 23.5 |
| | | (IPA) | |
| Cyclohexane | 16.8 | Acetonitrile | 24.0 |
| Amyl acetate | 17.3 | Ethanol | 26.4 |
| Butyl acetate | 17.4 | Dimethyl sulfoxide | 26.7 |
| | | (DMSO) | |
| Diethylene glycol | 17.8 | Methanol | 29.2 |
| diethyl ether | | | |
| Ethyl acetate | 18.2 | Water | 47.8 |

Note that in a case where two or more kinds of solvents are used in combination in the protective film forming agent for a silicon-based substrate according to the present embodiment, the SP value of a mixed solvent of the two or more kinds of solvents needs only to be 17.5 or less. The SP value of the mixed solvent can be obtained by summing the root-mean-square value of the sum regarding each of the dispersion force term δ_{d}, the polarity term δₚ, and the hydrogen bond term δₕ constituting the SP value of each solvent, the sum being weighted by a volume ratio of each solvent. For example, in the case of a mixed solvent containing a solvent A, a solvent B, and a solvent C at a proportion of 30% by volume, 20% by volume, and 50% by volume, respectively, the SP value of the mixed solvent can be obtained by the following formula (2). As for the solvent A, the dispersion force term, the polarity term, and the hydrogen bond term are δ_{dA}, δ_{pA}, and δ_{hA}, respectively. As for the solvent B, the dispersion force term, the polarity term, and the hydrogen bond term are δ_{aB}, δ_{pB}, and δ_{hB}, respectively. As for the solvent C, the dispersion force term, the polarity term, and the hydrogen bond term are δ_{dC}, δ_{pC}, and δ_{hC}, respectively.

$$The SP value of the mixed solvent = {( {( 0.3 \times {δ}_{dA} + 0.2 \times {δ}_{dB} + 0.5 \times {δ}_{dC} )}^{2} + {( 0.3 \times {δ}_{pA} + 0.2 \times {δ}_{pB} + 0.5 \times {δ}_{pC} )}^{2} + {( 0.3 \times {δ}_{h A} + 0.2 \times {δ}_{h B} + 0.5 \times {δ}_{h C} )}^{2} )}^{1 / 2} \qquad ( 2 )$$

The SP value needs only to be 17.5 or less, and the lower limit of the SP value is more preferably 10 or more, even more preferably 13 or more, even more preferably 15 or more, and even more preferably 15.5 or more. In addition, the upper limit of the SP value is preferably 17.3 or less, and more preferably 17.1 or less. In the case of a mixed solvent containing two or more kinds of solvents, the SP value of the mixed solvent is preferably in the above-described range.

In the case of a mixed solvent, for example, in a case where the SP value of at least one kind of solvent among solvents contained in the mixed solvent is within the above-described range (for example, 17.5 or less) and the SP values of the other solvents are outside the above-described range (for example, greater than 17), the SP value of the mixed solvent needs only to be 17.5 or less. However, the mixed solvent preferably contains only a solvent having an SP value of 17.5 or less.

The kind of the solvent is not particularly limited, but the solvent is preferably at least one kind selected from the group consisting of a hydrocarbon-based solvent, an ester-based solvent, and an ether-based solvent. The solvent is more preferably at least one kind selected from the group consisting of a hydrocarbon-based solvent, an ester-based solvent having one ester bond in a molecule, and an ether-based solvent having one ether bond in a molecule.

Specific examples of the hydrocarbon-based solvent used in the protective film forming agent for a silicon-based substrate according to the present embodiment are preferably hexane, heptane, octane, nonane, decane, undecane, dodecane, tridecane, tetradecane, pentadecane, hexadecane, and the like. Among these, decane, undecane, dodecane, and tridecane are more preferable.

Specific examples of the ester-based solvent used in the protective film forming agent for a silicon-based substrate according to the present embodiment are preferably ethyl acetate, propyl acetate, butyl acetate, isobutyl acetate, amyl acetate, hexyl acetate, butyl butyrate, dimethyl adipate, diethyl adipate, and the like. Among these, propyl acetate, butyl acetate, isobutyl acetate, amyl acetate, and hexyl acetate are more preferable.

Specific examples of the ether-based solvent used in the protective film forming agent for a silicon-based substrate according to the present embodiment are preferably diisopropyl ether, dibutyl ether, amyl ether, dimethoxyethane, diethoxyethane, and the like. Among these, dibutyl ether is more preferable.

Note that the protective film forming agent for a silicon-based substrate according to the present embodiment makes it possible to obtain a desired effect even if the protective film forming agent for a silicon-based substrate does not contain a thinner-based solvent. In addition, the protective film forming agent for a silicon-based substrate according to the present embodiment makes it possible to obtain the desired effect even if the protective film forming agent for a silicon-based substrate does not contain propylene glycol monomethyl ether acetate (PGMEA). Furthermore, the protective film forming agent for a silicon-based substrate according to the present embodiment makes it possible to obtain the desired effect even if the protective film forming agent for a silicon-based substrate does not contain propylene glycol methyl ether.

The content of the solvent in the protective film forming agent for a silicon-based substrate according to the present embodiment is not particularly limited, but is preferably 60% by mass or more and 99.5% by mass or less. The lower limit of the content is more preferably 70% by mass or more, even more preferably 80% by mass or more, and even more preferably 85% by mass or more. In addition, the upper limit of the content may be 99.3% by mass or less, may be 90% by mass or less, and may be 85% by mass or less. The content of the solvent is in such a range, whereby it is possible to further improve the property of inhibiting resist dissolution and the etching protective capability.

The total of the content of the hydrocarbon-based solvent, the ester-based solvent having one ester bond in a molecule, and the ether-based solvent having one ether bond in a molecule in the total amount of the solvent is not particularly limited, but is preferably 80% by mass or more and 100% by mass or less. The lower limit of the total of the content is more preferably 85% by mass or more, even more preferably 90% by mass or more, even more preferably 95% by mass or more, and even more preferably 98% by mass or more. Furthermore, the protective film forming agent for a substrate according to the present embodiment more preferably contains only the above-described solvent as a solvent. By setting such a proportion, it is possible to further improve the property of inhibiting resist dissolution and the etching protective capability.

The total of the content of the silylating agent and the content of the solvent in the protective film forming agent for a silicon-based substrate according to the present embodiment is not particularly limited, but is preferably 80% by mass or more and 100% by mass or less. The lower limit of the total of the content is more preferably 85% by mass or more, even more preferably 90% by mass or more, even more preferably 95% by mass or more, and even more preferably 98% by mass or more. In addition, as a component other than the solvent, the content of a component other than the silylating agent is preferably 20% by mass or less, more preferably 15% by mass or less, even more preferably 10% by mass or less, even more preferably 5% by mass or less, and even more preferably 2% by mass or less. The protective film forming agent for a silicon-based substrate according to the present embodiment is capable of achieving the desired effect even if the protective film forming agent for a silicon-based substrate is a forming agent containing only a silylating agent and a solvent.

### (Other Components)

The protective film forming agent for a silicon-based substrate according to the present embodiment may contain other components as components other than the above-described components. Examples of the other components may include pH adjusting agents such as organic acids and amines. Specific examples of the organic acids are preferably acetic acid, citric acid, phosphoric acid, sulfuric acid, methanesulfonic acid, and the like. Specific examples of the amines are more preferably tetramethylammonium hydroxide (TMAH), tetraethylammonium hydroxide (TEAH), ammonia (NH₃), ethylenediamine, diethylenetriamine, triethanolamine, and the like.

### <Method for Processing Silicon-Based Substrate>

The protective film forming agent for a silicon-based substrate according to the present embodiment can be suitably used for a method for processing a silicon-based substrate. A preferred example of the method for processing a silicon-based substrate according to the present embodiment may include a method for processing a silicon-based substrate, the method including:
(1) a step of subjecting, to oxidation processing, a surface of a silicon-based substrate including an organic film at least part of which is exposed; and
(2) a step of forming a protective film by bringing a protective film forming agent for a silicon-based substrate into contact with at least part of the surface of the silicon-based substrate subjected to the oxidation processing, in which
the protective film forming agent for a silicon-based substrate contains a silylating agent and a solvent having a Hildebrand SP value of 17.5 or less.

In the protective film forming agent for a silicon-based substrate used for the method for processing a silicon-based substrate according to the present embodiment, the above-described components, properties, conditions, and the like can be appropriately adopted, and redundant descriptions will be omitted. In addition, examples of the protective film formed in the method for processing a silicon-based substrate according to the present embodiment may include a film used as an etching protective film and the like.

The method for processing a silicon-based substrate according to the present embodiment can form a protective film including an organosilyl group on a silicon-based substrate without damaging resist, for example, by using the above-described protective film forming agent for a silicon-based substrate.

The silicon-based substrate used in the method for processing a silicon-based substrate according to the present embodiment preferably includes one or more kinds of materials selected from the group consisting of silicon oxide, carbon-containing silicon oxide, silicon nitride, silicon carbide, silicon carbonitride, silicon oxynitride, silicon oxycarbonitride, and silicon.

In the step (1), an exposed portion of the silicon-based substrate having a surface on which a patterned organic film is present and at least part of the patterned organic film is exposed is subjected to oxidation processing. An example of the exposed organic film may include photoresist. A method for the oxidation processing is not particularly limited, and can be performed, for example, through oxidation processing using a hydrogen peroxide-containing chemical solution, ozone water, or the like. In addition, before and after the step (1), pre-processing or post-processing such as HF washing and water washing may be performed as necessary. By performing the oxidation processing, for example, a film of silicon oxide (SiO₂) can be formed, and reactivity with a protective film-forming material is improved.

The step (2) is preferably a step of forming the protective film by immersing at least part of the surface of the silicon-based substrate subjected to the oxidation processing in the protective film forming agent for a silicon-based substrate. A method for immersing in the protective film forming agent for a silicon-based substrate is preferably, for example, a method called a wet method. As compared with a so-called vapor method in which a protective film forming agent for a silicon-based substrate is converted into vapor and brought into contact with a substrate, the wet method is excellent in that a protective film having higher protective capability can be formed on a silicon-based substrate.

An immersion condition in the step (2) is not particularly limited, but for example, immersion temperature is 20° C. or more and 60° C. or less. The lower limit of the immersion temperature may be 25° C. or more, and may be 30° C. or more. In addition, the upper limit of the immersion temperature may be 45° C. or less, and immersion time is, for example, one minute or more and 30 minutes or less. The upper limit of the immersion time may be 20 minutes or less, may be 15 minutes or less, and may be 10 minutes or less.

### <Method for Processing Silicon-Based Substrate>

The protective film forming agent for a silicon-based substrate according to the present embodiment and the method for processing a silicon-based substrate according to the present embodiment can be suitably used in a method for manufacturing a semiconductor device. A preferred example of the method for manufacturing a semiconductor device according to the present embodiment is a method for manufacturing a semiconductor device, the method including:
(1) a step of subjecting, to oxidation processing, a surface of a silicon-based substrate including an organic film at least part of which is exposed; and
(2) a step of forming a protective film by bringing a protective film forming agent for a silicon-based substrate into contact with at least part of the surface of the silicon-based substrate subjected to the oxidation processing, in which
the protective film forming agent for a silicon-based substrate contains a silylating agent and a solvent having a Hildebrand SP value of 17.5 or less.

In the protective film forming agent for a silicon-based substrate used for the method for processing a silicon-based substrate according to the present embodiment, the above-described components, properties, conditions, and the like can be appropriately adopted, and redundant descriptions will be omitted. Similarly, among the matters described as the method for processing a silicon-based substrate according to the present embodiment, redundant description will be omitted.

The silicon-based substrate preferably includes one or more kinds of materials selected from the group consisting of silicon oxide, carbon-containing silicon oxide, silicon nitride, silicon carbide, silicon carbonitride, silicon oxynitride, silicon oxycarbonitride, and silicon.

Examples of the protective film formed in the step (1) may include a film used as an etching protective film and the like.

The step (2) is preferably a step of forming the protective film by immersing at least part of the surface of the silicon-based substrate subjected to the oxidation processing in the protective film forming agent for a silicon-based substrate. A method for immersing in the protective film forming agent for a silicon-based substrate is preferably, for example, a method called a wet method, as described above. As compared with a so-called vapor method in which a protective film forming agent for a silicon-based substrate is converted into vapor and brought into contact with a substrate, the wet method is excellent in that a stronger protective film can be formed on a silicon-based substrate without damaging resist.

The method for manufacturing a semiconductor device according to the present embodiment preferably further includes a step of etching the silicon-based substrate on which the protective film is formed after the step (2). An etching method is not particularly limited, and a known method can be adopted. Examples of the etching method may include methods such as wet etching using an aqueous solution of an acid or a base such as hydrofluoric acid, nitric acid, sulfuric acid, phosphoric acid, or tetramethylammonium hydroxide (TMAH) and dry etching using reactive ions. In addition, after an etching step, post-processing such as isopropyl alcohol (IPA) cleaning or water cleaning may be performed as necessary.

As described above, the protective film forming agent for a silicon-based substrate, the method for processing a silicon-based substrate, and the method for manufacturing a semiconductor device according to the present embodiment make it possible to form a protective film on a silicon-based substrate without damaging resist. As a result, it is expected that a semiconductor device excellent in etching selectivity, wiring pattern accuracy, and the like can be manufactured.

### EXAMPLES

The present invention will be described in more detail with reference to the following Examples and Comparative Examples, but the present invention is not limited to the following Examples at all. Note that unless otherwise specified, numbers in the present Examples are on a mass basis.

### <Preparation of Protective Film Forming Agent for Silicon-Based Substrate>

Protective film forming agents for a silicon-based substrate having compositions shown in Table 2 were prepared. For example, Example 1 is a protective film forming agent for a silicon-based substrate, the protective film forming agent containing 7% by mass of trimethylsilyldimethylamine (TMSDMA) and containing balance decane as a solvent. In addition, the Hildebrand SP value of decane is 15.7.

### <Components Used>

Note that abbreviations and the like described in each table are as follows.
HMDS: hexamethyldisilazane
TMSDMA: trimethylsilyldimethylamine
BDMADMS: bisdimethylaminodimethylsilane
PGMEA: propylene glycol monomethyl ether acetate (thinner-based solvent)

### <Measurement of Film Thickness>

Film thickness was measured using spectroscopic ellipsometry (“M-2000 (registered trademark) UI” manufactured by J.A. Woollam Japan).

### <Evaluation of Resist Dissolution Inhibiting Property>

A resist liquid (Positive KrF resist for lines, trade name “TDUR-P3435”, manufactured by TOKYO OHKA KOGYO CO., LTD.) was applied onto a silicon substrate (Si substrate), and then baked at 100° C. for 60 seconds to obtain a multilayer substrate on which resist was formed. This multilayer substrate was cut into 1 cm by 2 cm to obtain a sample. Then, the film thickness of the resist of the sample (film thickness before processing) was measured.

Subsequently, the sample was immersed in a protective film forming agent for a silicon-based substrate of each of Examples and Comparative Examples for 10 minutes, and then washed with water to obtain the sample after processing. Then, the film thickness of the resist of the sample after processing (film thickness after processing) was measured. The film loss amount of the resist was determined from the film thickness before processing and the film thickness after processing, and the solubility of the resist was evaluated on the basis of the following criteria.
A: The film loss amount of the resist was less than 2 nm.
B: The film loss amount of the resist was 2 nm or more.

### <Evaluation of Etching Protective Capability>

The etching protective capability of SiO₂ and the etching protective capability of SiN were each evaluated in accordance with the following procedure.

### (1) Sample Preparation

A multilayer substrate with an SiO₂ film or an SiN film formed on a silicon substrate (Si substrate) was obtained by a PVD method. Then, the multilayer substrate was cut into 1 cm by 2 cm to obtain a sample. First, the film thickness of the sample (film thickness before processing) was measured.

### (2) Pre-Processing

Next, as pre-processing, the sample was immersed in 0.5% by mass of hydrogen fluoride water (HF water) for one minute, and then washed and dried. Thereafter, the sample was heated to 50° C., immersed in standard clean 1 (SC1: cleaning liquid mixed in a mass ratio of NH₄OH:H₂O₂:H₂O=1:1:50) for one minute, further washed with water, and then dried.

### (3-1) Protective Film Forming Processing (Vapor Processing)

In the case of vapor processing, the processing was performed as follows. The sample subjected to the pre-processing was placed in a chamber, and the inside of the chamber was replaced with nitrogen gas. Thereafter, the sample was heated to 90° C. and vaporized hexamethyldisilazane (HMDS, see Comparative Example 1) was sprayed onto the sample for 60 seconds. Thereafter, the sample was immersed in 0.5% by mass of hydrogen fluoride water (HF water) for one minute, washed with water, and dried. Then, the film thickness of the sample (film thickness after processing) was measured.

### (3-2) Protective Film Forming Processing (Wet Processing)

In the case of wet processing, the processing was performed as follows. The sample subjected to the pre-processing was immersed in a beaker containing the protective film forming agent for a silicon-based substrate of each of Examples and Comparative Examples at a processing temperature described in Table 2 for three minutes. Thereafter, the sample was washed with decane (organic solvent), blown with nitrogen gas, and dried. The sample was immersed in 0.5% by mass of hydrogen fluoride water (HF water) for one minute, washed with water, and dried. Then, the film thickness of the sample (film thickness after processing) was measured.

### (4) Evaluation of Etching Protective Capability

An etching amount was obtained from the film thickness before processing and the film thickness after processing, and the etching protective capability was evaluated on the basis of the following criteria.
A: The etching amount was reduced by 0 to 50% by protective film-forming agent processing as compared with a condition without protective film-forming agent processing.
B: The etching amount was reduced by 51 to 80% by the protective film-forming agent processing as compared with the condition without protective film-forming agent processing.
C: The etching amount was reduced by 81 to 100% by the protective film-forming agent processing as compared with the condition without protective film-forming agent processing.

Table 2 shows a composition and an evaluation result of each of Examples and Comparative Examples. Note that “Mixing Ratio” in “Solvent” in the table is a volume ratio. For example, “Decane+Butyl acetate (Mixing ratio 7:3)” in Example 6 means a mixed solvent containing decane and butyl acetate at a volume ratio of decane:butyl acetate=7:3.

TABLE 2

| | | | | | | Resist | Etching | |
|---|---|---|---|---|---|---|---|---|
| | | | | | Processing | dissolution | protective | |
| | | | Processing | SP | temperature | inhibiting | capability | |
| | Silylating agent | Solvent | method | value | (° C.) | property | SiO₂ | SiN |
| Comparative | HMDS | None | Vapor | — | — | A | C | C |
| Example 1 | | | | | | | | |
| Comparative | 7% TMSDMA | PGMEA | Wet | 19.3 | 40 | B | B | C |
| Example 2 | | | | | | | | |
| Example 1 | 7% TMSDMA | Decane | Wet | 15.7 | 40 | A | A | A |
| Example 2 | 7% TMSDMA | Dibutyl | Wet | 15.9 | 40 | A | A | A |
| | | ether | | | | | | |
| Example 3 | 7% TMSDMA | Butyl | Wet | 16.8 | 40 | A | A | A |
| | | butyrate | | | | | | |
| Example 4 | 7% TMSDMA | Tridecane | Wet | 15.6 | 40 | A | A | A |
| Example 5 | 7% TMSDMA | Tetradecane | Wet | 15.6 | 40 | A | A | A |
| Example 6 | 7% TMSDMA | Decane + | Wet | 15.9 | 40 | A | A | A |
| | | Butyl | | | | | | |
| | | acetate | | | | | | |
| | | (Mixing | | | | | | |
| | | ratio 7:3) | | | | | | |
| Example 7 | 7% BDMADMS | Decane | Wet | 15.7 | 40 | A | A | A |
| Example 8 | 10% HMDS | Decane | Wet | 15.7 | 40 | A | A | B |
| Example 9 | 7% TMSDMA | Decane | Wet | 15.7 | 25 | A | A | A |
| Example 10 | 15% TMSDMA | Decane | Wet | 15.7 | 40 | A | A | A |
| Example 11 | 3% TMSDMA | Decane | Wet | 15.7 | 40 | A | A | A |
| Example 12 | 1% TMSDMA | Decane | Wet | 15.7 | 40 | A | A | B |
| Example 13 | 7% TMSDMA | Decane + | Wet | 16 | 40 | A | A | A |
| | | Amyl | | | | | | |
| | | acetate | | | | | | |
| | | (Mixing | | | | | | |
| | | ratio 6:4) | | | | | | |
| Example 14 | 7% TMSDMA | Decane + | Wet | 16.8 | 40 | A | A | A |
| | | Amyl | | | | | | |
| | | acetate | | | | | | |
| | | (Mixing | | | | | | |
| | | ratio 2:8) | | | | | | |
| Example 15 | 7% TMSDMA | Decane + | Wet | 17.1 | 40 | B | A | A |
| | | Amy1 | | | | | | |
| | | acetate | | | | | | |
| | | (Mixing | | | | | | |
| | | ratio 1:9) | | | | | | |

From the above, it was at least confirmed that the protective film forming agents for a silicon-based substrate according to the present Examples are excellent in the resist dissolution inhibiting property and the etching protective capability. In addition, it was at least confirmed that the protective film forming agents for a silicon-based substrate according to the present Examples are used, whereby protective films can be formed on the silicon-based substrate without damaging the resist.

What is claimed is:

1. A protective film forming agent for a silicon-based substrate, the protective film forming agent comprising:
a silylating agent; and
a solvent having a Hildebrand SP value of 17.5 or less.

2. The protective film forming agent for a silicon-based substrate according to claim 1, wherein
the silylating agent is at least one kind selected from the group consisting of hexamethyldisilazane, trimethylsilyldimethylamine, and bisdimethylaminodimethylsilane.

3. The protective film forming agent for a silicon-based substrate according to claim 1, wherein
the solvent is at least one kind selected from the group consisting of a hydrocarbon-based solvent, an ester-based solvent having one ester bond in a molecule, and an ether-based solvent having one ether bond in a molecule.

4. The protective film forming agent for a silicon-based substrate according to claim 1, wherein
the content of the silylating agent is 1% by mass or more and 20% by mass or less.

5. The protective film forming agent for a silicon-based substrate according to claim 1, wherein
a total of the content of a hydrocarbon-based solvent, an ester-based solvent having one ester bond in a molecule, and an ether-based solvent having one ether bond in a molecule is 80% by mass or more and 100% by mass or less in a total amount of the solvent.

6. The protective film forming agent for a silicon-based substrate according to claim 1, wherein
a total of the content of the silylating agent and the content of the solvent in the protective film forming agent for a silicon-based substrate is 80% by mass or more and 100% by mass or less.

7. The protective film forming agent for a silicon-based substrate according to claim 1, wherein
a protective film can be formed on a silicon-based substrate including an organic film at least part of which is exposed.

8. A method for processing a silicon-based substrate, the method comprising:
(1) a step of subjecting, to oxidation processing, a surface of a silicon-based substrate including an organic film at least part of which is exposed; and
(2) a step of forming a protective film by bringing a protective film forming agent for a silicon-based substrate into contact with at least part of the surface of the silicon-based substrate subjected to the oxidation processing, wherein
the protective film forming agent for a silicon-based substrate contains a silylating agent and a solvent having a Hildebrand SP value of 17.5 or less.

9. The method for processing a silicon-based substrate according to claim 8, wherein
the step (2) is a step of forming the protective film by immersing at least part of the surface of the silicon-based substrate subjected to the oxidation processing in the protective film forming agent for a silicon-based substrate.

10. The method for processing a silicon-based substrate according to claim 8, wherein
the silicon-based substrate includes one or more kinds of materials selected from the group consisting of silicon oxide, carbon-containing silicon oxide, silicon nitride, silicon carbide, silicon carbonitride, silicon oxynitride, silicon oxycarbonitride, and silicon.

11. A method for manufacturing a semiconductor device, the method comprising:
(1) a step of subjecting, to oxidation processing, a surface of a silicon-based substrate including an organic film at least part of which is exposed;
(2) a step of forming a protective film by bringing a protective film forming agent for a silicon-based substrate into contact with at least part of the surface of the silicon-based substrate subjected to the oxidation processing, wherein
the protective film forming agent for a silicon-based substrate contains a silylating agent and a solvent having a Hildebrand SP value of 17.5 or less.

12. The method for manufacturing a semiconductor device according to claim 11, wherein
the step (2) is a step of forming the protective film by immersing at least part of the surface of the silicon-based substrate subjected to the oxidation processing in the protective film forming agent for a silicon-based substrate.

13. The method for manufacturing a semiconductor device according to claim 11, further comprising, after the step (2),
a step of etching the silicon-based substrate on which the protective film is formed.

14. The method for manufacturing a semiconductor device according to claim 11, wherein
the silicon-based substrate includes one or more kinds of materials selected from the group consisting of silicon oxide, carbon-containing silicon oxide, silicon nitride, silicon carbide, silicon carbonitride, silicon oxynitride, silicon oxycarbonitride, and silicon.
